(19) United States
(12) Patent Application Publication
(10) Pub. No.: US 2014/0110685 A1
(43) Pub. Date: Apr. 24, 2014

(54) METHOD FOR PREPARING DESICCANT LAYER, OLED DISPLAY PANEL AND METHOD FOR PACKAGING THE SAME

(71) Applicant: BOE Technology Group Co., Ltd., Beijing (CN)

(72) Inventors: Rui Hong, Beijing (CN); Joo Hyeon Lee, Beijing (CN); Dong Hwan Kim, Beijing (CN)

(73) Assignee: BOE Technology Group Co., Ltd., Beijing (CN)

(21) Appl. No.: 14/055,069

(22) Filed: Oct. 16, 2013

(30) Foreign Application Priority Data
Oct. 18, 2012 (CN) 201210397385.0

(51) Int. Cl. H01L 51/56; H01L 51/52; H01L 27/32

(52) U.S. Cl. CPC H01L 51/56; H01L 27/32; H01L 51/524
USPC 257/40; 257/99; 438/26

(57) ABSTRACT

A method for packaging an organic light emitting diode display panel, comprising providing a desiccant layer on a package cover plate. The desiccant layer is capable of effectively absorbing water and oxygen permeating, edges of the package cover plate and a substrate are hermetically coupled, and the desiccant layer and a device on the substrate are enclosed in a packaging cavity. This method can improve the packaging efficiency of the organic light emitting diode display panel and reduces production costs.

### TECHNICAL FIELD

Embodiments of the present technical disclosure relate to a method for preparing a desiccant layer, an Organic Light Emitting Diode (OLED) display panel and a method for packaging the same.

### BACKGROUND

Active Matrix-Organic Light Emitting Diode (AM-OLED) display panels have advantages such as wide viewing angle, fast response, high operation temperature, ultra-thin profile, etc., and can realize flexible display, transparent display and so on. AM-OLED display panels can be classified into top-emission AM-OLED display panels that emit light from the top of the display panels and bottom-emission AM-OLED display panels that emit light from the bottom of the display panels. In comparison, the top-emission AM-OLED display panels generally have a higher aperture ratio, and can achieve a higher luminance. However, because the light must be emitted from the top of the display panels, a material blocking light can't be disposed at the top of the top-emission AM-OLED display panels.

A conventional AMOLED employing a slice-shaped desiccant (i.e., drying sheets 103) is illustrated in FIG. 1. To ensure lifetime of device of an OLED display panel, drying sheets 103 usually have a thickness in the range of 0.1-0.2 mm, and moreover, the drying sheets 103 need to be attached layer by layer to the recesses of a package sheet 102 to avoid contact of the drying sheets 103 with devices 104 provided on a substrate 101. Thus, it is required that a glass package sheet with recesses be used to package the display panel, and it is required that sealant 105 be used to coupled edges of the package sheet 102 and the substrate 101.

Because the package sheet needs to be processed and the drying sheets need to be attached layer by layer, this package technology has relatively low production efficiency. And, owing to the use of the package sheet with recesses, the cost is relatively high.

### SUMMARY

According to embodiments of the present technical disclosure, there are provided a method for preparing a desiccant layer, an Organic Light Emitting Diode (OLED) display panel and a method for packaging the same, so as to improve the packaging efficiency of the organic light emitting diode display panel and reduce production cost.

In one aspect of the technical disclosure, there is provided an OLED display panel, comprising a substrate and a device disposed on the substrate; a package cover plate, hermetically coupled to edges of the substrate so as to form a package cavity for packaging the device; and a desiccant layer disposed on a side of the package cover plate facing the package cavity and for drying the device.

In another aspect of the technical disclosure, there is provided a method for packaging an OLED display panel, comprising: providing a desiccant layer on a package cover plate that is for drying a device on a substrate; hermetically coupling edges of the package cover plate and the substrate, and sealing the desiccant layer and the device on the substrate within a package cavity formed by the package cover plate and the substrate.

In still another aspect of the technical disclosure, there is provided a method for preparing a desiccant layer, comprising: placing an alkaline earth metal target, a metal mask and the package cover plate in a sealed chamber; evacuating air in the sealed chamber so as to form a vacuum chamber; pumping oxygen gas into the vacuum chamber; and applying a high frequency power to the vacuum chamber.

In yet still another aspect of the technical disclosure, there is provided a display device, comprising the OLED display panel provided by an embodiment of the technical disclosure.

Further scope of applicability of the present technical disclosure will become apparent from the detailed description given hereinafter. However, it should be understood that the detailed description and specific examples, while indicating preferred embodiments of the technical disclosure, are given by way of illustration only, since various changes and modifications within the spirit and scope of the technical disclosure will become apparent to those skilled in the art from the following detailed description.

### BRIEF DESCRIPTION OF THE DRAWINGS

The present technical disclosure will become more fully understood from the detailed description given hereinafter and the accompanying drawings which are given by way of illustration only, and thus are not limitative of the present technical disclosure and wherein:

FIG. 1 is a diagram illustrating a conventional OLED display panel;

FIG. 2 is a diagram illustrating an OLED display panel provided by an embodiment of the technical disclosure;

FIG. 3 is a flow chart illustrating a method for packaging an OLED display panel provided by an embodiment of the technical disclosure;

FIG. 4 is a flow chart illustrating a method for packaging an OLED display panel with sealant provided by an embodiment of the technical disclosure;

FIG. 5 is a diagram illustrating a method for preparing a desiccant layer provided by an embodiment of the technical disclosure.

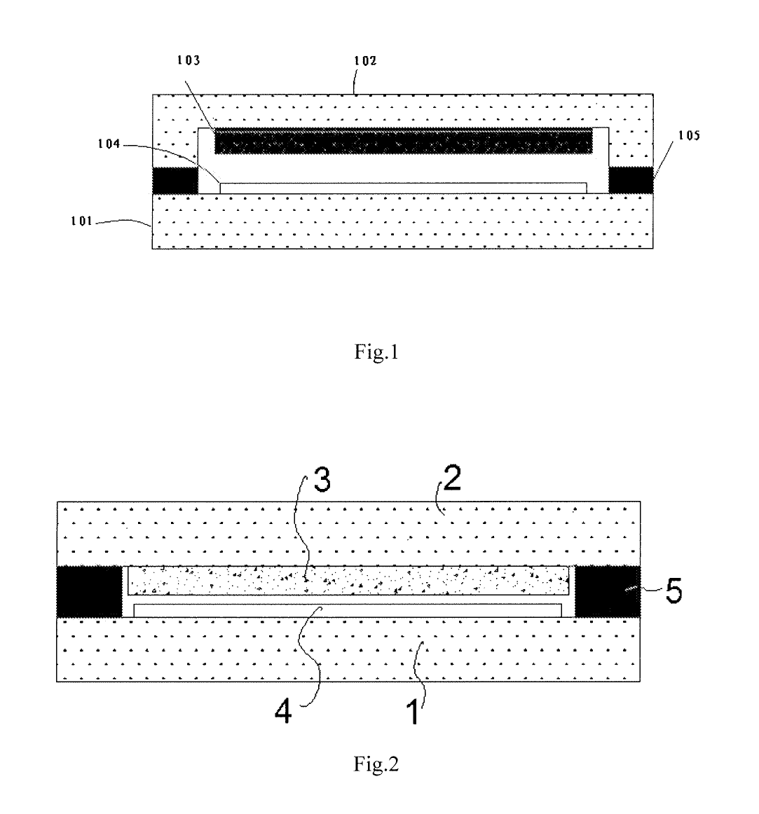

### DETAILED DESCRIPTION

According to embodiments of the technical disclosure, there are provided a method for preparing a desiccant layer, an organic light emitting diode display panel and a method for packaging the same. The desiccant layer (dying agent layer) is arranged on a package cover plate and is capable of effectively absorbing water and oxygen permeating into the package cavity. The edges of the package cover plate and a substrate are hermetically coupled, and the desiccant layer and a device on the substrate are enclosed in the resultant package cavity. In the organic light emitting diode display panel provided by an embodiment of the technical disclosure, because the desiccant layer is employed, and the desiccant layer can be directly formed on the package cover plate, it is unnecessary to use a conventional non-transparent, slice-shaped desiccant sheets and to attach the desiccant sheets layer by layer to recesses of a package sheet, and it is also unnecessary to manufacture the package sheet with recesses, and this improves the packaging efficiency of the organic light emitting diode display panel and reduces the production cost.

As illustrated in FIG. 2, an organic light emitting diode display panel according to an embodiment of the technical disclosure is provided, comprising a substrate 1 and an (electroluminescent) device 4 disposed on the substrate 1, as well as a package cover plate 2 and a desiccant layer (dying agent layer) 3. The edges of the package cover plate 2 and the substrate 1 are hermetically coupled so as to form a package cavity between them for packaging the device 4 therein; the desiccant layer 3 is arranged on the side of the package cover plate 2 facing the package cavity and used to dry the device 4. The device 4 may be an OLED device, and according to requirements, it may adopt various structures, such as a top-emission structure or a bottom-emission structure.

The package cover plate 2 is utilized to form the package cavity together with the substrate 1, the desiccant layer 3 is arranged on the package cover plate 2 to dry the device 4, and the desiccant layer 3 and the device 4 on the substrate are hermetically enclosed within the package cavity that is formed by hermetically coupling edges of the package cover plate 2 and the substrate 1. Due to the use of the desiccant layer 3 and reduction in thickness of the desiccant layer 3 to a great degree as compared with the traditional desiccant sheets, it is unnecessary to use a package sheet with recesses. The desiccant layer 3 can be directly formed on the package cover plate 2 through vacuum coating or other process, and thus, as compared to the case where desiccant sheets need to be attached to the recess layer by layer when they are used, the process according to the embodiment of the technical disclosure is more simple and convenient, thereby improving the packaging efficiency of the OLED display panel.

For example, the side of the package cover plate 2 that forms the package cavity together with the substrate 1 is a flat surface.

For example, because the water absorption property of alkaline earth metal oxides is excellent, the material of the desiccant layer 3 may be an alkaline earth metal oxide, and preferably, barium oxide or calcium oxide may be used for the material of the desiccant layer 3.

For example, the material of the desiccant layer 3 may further be a metal getter layer, and preferably, it may adopt zirconium cobalt and an alloy of a rare earth metal.

Of course, those skilled in the art can also adopt other material suitable for the desiccant layer 3.

With respect to the OLED display panel provided by the embodiment of the technical disclosure, the thickness of the desiccant layer 3 is determined according to water absorption property of the material.

For example, when the desiccant layer 3 is an alkaline earth metal oxide layer, the thickness of the desiccant layer 3 may be in the range of 1-30 μm.

According to testing result, transmittance of a calcium oxide thin film with a thickness of 20 μm in the wavelength range of 400-900 um is about 85%, and therefore the desiccant layer 3 formed of the alkaline earth metal oxide can ensure that light emitting from the top-emission OLED display panel is not blocked.

Certainly, those skilled in the art may use other feasible way to select a suitable thickness for the desiccant layer 3.

For example, regarding the OLED display panel provided by the embodiment of the technical disclosure, the package cover plate 2 may be a glass package cover plate or a metal package cover plate. For example, for a top-emission OLED display panel, a glass cover plate may be used for packaging so as to ensure that light emitting from the top-emission OLED display panel is not blocked, while for a bottom-emission OLED display panel, a glass package cover plate or a metal package cover plate may be used.

For example, because drying sheet with a larger thickness needs not to be used, and no recesses needs to be provided on the package cover plate 2, the package cover plate 2 can adopt a glass plate with a smaller thickness so as to reduce the thickness of the OLED display panel. For example, the thickness of the OLED display panel can be controlled to be about 0.8 mm.

Of course, those skilled in the art may employ other available material to provide the package cover plate 2.

For example, regarding the OLED display panel provided by the embodiment of the technical disclosure, edges of the package cover plate 2 and the substrate 1 may be hermetically coupled through sealant 5. In order to avoid the contact of the desiccant layer 3 with the device 4 so as to prevent the adverse effect of the desiccant layer 3 on the performance of the device 4, the thickness of the sealant 5 is set to be larger than the sum of the thickness of the desiccant layer 3 and the thickness of the device 4. For example, when the thickness of the desiccant layer 3 is in the range of 1-30 μm, the thickness of the sealant 5 may be set to be in the range of 6-40 μm accordingly, namely, the thickness of the sealant 5 is usually larger than the thickness of the desiccant layer by 5-10 μm.

For example, when the sealant 5 is used for packaging, it is possible that the sealant 5 is firstly coated along the edges of the package cover plate 2 or the substrate 1 so as to ensure that the thickness of the sealant 5 is larger than the sum of the thickness of the desiccant layer and the thickness of the device, the package cover plate 2 and the substrate 1 are pressed so as to ensure hermetic coupling between the package cover plate 2 and the substrate 1, and the sealant 5 can be irradiated with ultraviolet (UV) so as to accelerate cure of the sealant.

Certainly, those skilled in the art may use other feasible way to select the thickness of the sealant 5; and those skilled in the art may use other way to hermetically couple the edges of the package cover plate 2 and the substrate 1 as well.

For example, the desiccant layer 3 may be arranged on the package cover plate 2 by means of vacuum coating, and the desiccant layer 3 is formed with a certain thickness and a shape through a metal mask plate, so as to be comparable with the type, shape and package on the device to be dried, thereby realizing simplification of the process. The metal mask plate may be a mask plate employed in a traditional semiconductor manufacturing process, which shields selected areas so that the subsequent operations can only conducted upon the non-shielded areas only.

For example, in one embodiment of the technical disclosure, the process to provide the desiccant layer 3 on the package cover plate 2 may be conducted as follows. The desiccant layer 3 is provided on the package cover plate 2 through evaporation coating with a metal mask plate; or the desiccant layer 3 is provided on the package cover plate 2 through electron beam evaporation with a metal mask plate; or the desiccant layer 3 is provided on the package cover plate 2 through magnetron sputtering with a metal mask plate; or the desiccant layer 3 is provided on the package cover plate 2 through physical vapor deposition (PVD) or chemical vapor deposition (CVD) with a metal mask plate.

Providing the desiccant layer 3 with a metal mask plate can make the formed desiccant layer 3 meet requirements on thickness and shape, thereby simplifying the process and improving the efficiency.

Certainly, those skilled in the art may use other feasible way to provide the desiccant layer 3.

For example, as the desiccant layer 3 is provided on the package cover plate 2 through magnetron sputtering with a metal mask plate, magnetron reactive sputtering in the magnetron sputtering may be employed for forming the desiccant layer 3.

According to an embodiment of the technical disclosure, there is provided a method of providing a desiccant layer 3 on a package cover plate 2 through magnetron reactive sputtering with a metal mask plate.

For example, providing the desiccant layer 3 on the package cover plate 2 through magnetron reactive sputtering with a metal mask plate may be conducted as follows. An alkaline earth metal target, a metal mask and the package cover plate are placed in a sealed chamber; air in the sealed chamber is evacuated so as to form a vacuum chamber; oxygen gas is pumped into the vacuum chamber; and a high frequency power supply is applied to the vacuum chamber.

For example, the alkaline earth metal target may be a target having a single ingredient, such as a calcium target or barium target, or may also be a target of an alloy of metals, such as an alloy target of calcium and barium. Moreover, the metal target may contain a small amount of rare earth metal, for example, 5 wt % of yttrium or lanthanum.

The alkaline earth metal target, the metal mask and the package cover plate are placed in the sealed chamber, for example, it is possible that the metal mask plate and the package cover plate are precisely aligned with a visual aligning (CCD) system, so as to ensure that the prepared desiccant layer is accurately positioned in the package area.

For example, after the alkaline earth metal target, the metal mask and the package cover plate are placed in the sealed chamber, air in the sealed chamber is evacuated to achieve a base vacuum of 1.0×10⁻⁵ Pa, so that a vacuum chamber is obtained; oxygen gas is then pumped into the vacuum chamber so as to keep the vacuum degree between 0.01 Pa and 1 Pa; and next a radio frequency power is turn on for oxygen ionization, and ionized oxygen ions and metal ions react to produce a metal oxide, which is attached to the package cover plate to form the desiccant layer. For example, a high frequency power, such as a RF power at 13.56 MHZ, may be used as the radio frequency power.

When the desiccant layer is provided on the package cover plate through magnetron sputtering with a metal mask plate, providing of the desiccant layer 3 can be achieved simply, conveniently and fast, thereby simplifying the process and improving the efficiency of packaging the OLED display panel.

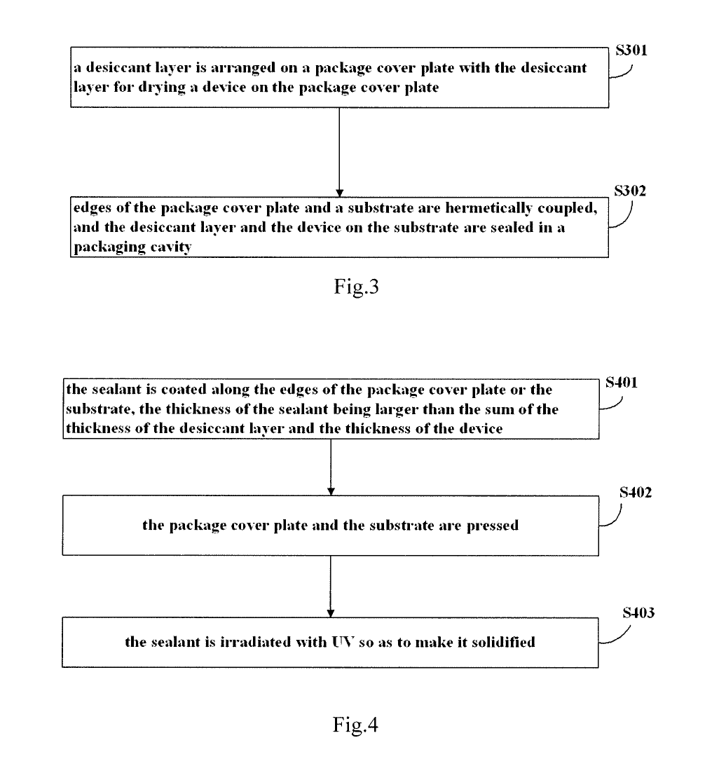

As illustrated in FIG. 3, according to an embodiment of the technical disclosure, there is provided a method for packaging an OLED display panel, which is conducted as follows:

S301, a desiccant layer 3 is arranged on a package cover plate 2 with the desiccant layer 3 functioning to dry a device 4 on the package cover plate;

S302, edges of the package cover plate 2 and a substrate 1 are hermetically coupled, and the desiccant layer 3 and the device 4 on the substrate are sealed in a package cavity formed by the package cover plate 2 and the substrate 1.

The package cover plate 2 is utilized to form the package cavity together with the substrate 1, the desiccant layer 3 is arranged on the package cover plate 2 to dry the device 4, and the desiccant layer 3 and the device 4 on the substrate are hermetically enclosed within the package cavity that is formed by coupling the edges of the package cover plate 2 and the substrate 1. Due to the use of the desiccant layer 3 with a great degree reduced thickness compared with traditional desiccant sheets, it is unnecessary to use a package sheet with recesses. The desiccant layer 3 is directly formed on the package cover plate 2 through vacuum coating or other process, and as compared to the case where desiccant sheets need to be attached layer by layer to the recesses when they are used, the process according to the embodiment is more simple and convenient, thereby improving the packaging efficiency of the OLED display panel.

For example, regarding the OLED display panel provided by the embodiment of the technical disclosure, the edges of the package cover plate 2 and the substrate 1 may be hermetically coupled through sealant 5. In order to avoid the contact of the desiccant layer 3 with the device 4 so as to prevent the adverse effect of desiccant layer 3 on the performance of the device 4, the thickness of the sealant 5 may be set to be larger than the sum of the thickness of the desiccant layer 3 and the thickness of the device 4. For example, when the thickness of the desiccant layer 3 is in the range of 1-30 μm, the thickness of the sealant 5 may be set to be in the range of 6-40 μm accordingly, namely, the thickness of the sealant 5 is usually larger than the thickness of the desiccant layer 3 by 5-10 μm.

For example, when the sealant 5 is used for packaging, it is possible that the sealant 5 is firstly coated along the edges of the package cover plate 2 or the substrate 1 so as to ensure that the thickness of the sealant 5 is larger than sum of thickness of the desiccant layer 3 and the device 4, the package cover plate 2 and the substrate 1 is pressed so as to ensure hermetic coupling between the package cover plate 2 and the substrate 1, and the sealant 5 is irradiated with ultraviolet (UV) so as to accelerate curing of the sealant.

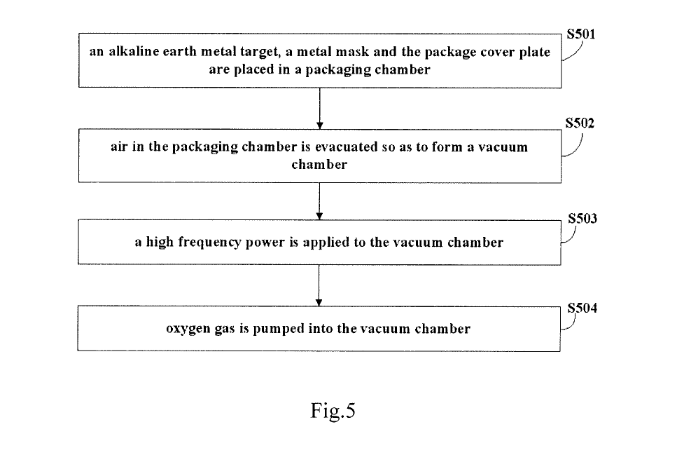

For example, as illustrated in FIG. 4, an exemplary procedure of packaging with the sealant can be conducted as follows:

S401, the sealant 5 is coated along the edges of the package cover plate 2 or the substrate 1, the thickness of the sealant 5 being larger than the sum of the thickness of the desiccant layer 3 and the thickness of the device 4;

S402, the package cover plate 2 and the substrate 1 are pressed;

S403, the sealant 5 is irradiated with UV so as to make it cured.

Certainly, those skilled in the art may use other feasible way to set the thickness of the sealant 5; and of course, those skilled in the art may hermetically couple the edges of the package cover plate 2 and the substrate 1 by other methods.

For example, regarding the OLED display panel provided by the embodiment of the technical disclosure, the package cover plate 2 may be a glass package cover plate or a metal package cover plate. For example, for a top-emission OLED display panel, a glass cover plate may be used for packaging so as to ensure that light emitting from the top-emission OLED display panel is not blocked, while for a bottom-emission OLED display panel, a glass package cover plate or a metal package cover plate may be used.

For example, because it is not necessary to use the drying sheet with a larger thickness, and it is not necessary to use the package cover plate 2 with recesses, the package cover plate 2 can adopt a glass plate with a smaller thickness, so as to reduce the thickness of the OLED display panel. For example, the thickness of the OLED display panel can be controlled to be about 0.8 mm.

Of course, those skilled in the art may employ other available material to set the package cover plate 2.

For example, because the water absorption property of alkaline earth metal oxides is excellent, the material for the desiccant layer 3 may be an alkaline earth metal oxide. For example, barium oxide or calcium oxide may be used for the material of the desiccant layer 3.

Of course, those skilled in the art can adopt other available material to form the desiccant layer 3.

With respect to the OLED display panel provided by the embodiment of the technical disclosure, the thickness of the desiccant layer 3 can be determined according to the water absorption property of the material.

For example, when the desiccant layer 3 is an alkaline earth metal oxide layer, the thickness of the desiccant layer 3 is in the range of 1-30 μm.

According to the testing result, the transmittance of a calcium oxide thin film with a thickness of 20 μm in the wavelength range of 400-900 um is about 85%, and therefore the desiccant layer 3 formed of the alkaline earth metal oxide can ensure that light emitting from the top-emission OLED display panel is not blocked.

Certainly, those skilled in the art may use other feasible way to select the thickness of the desiccant layer 3.

For example, the desiccant layer 3 may be arranged on the package cover plate 2 by means of vacuum coating, in which the desiccant layer 3 is formed with a certain thickness and a shape, so as to be comparable with the type, shape and package on the device to be dried, thereby realizing simplification of the process. The metal mask plate may be a mask plate employed in a traditional semiconductor manufacturing process, which shields selected areas so that the subsequent operations can only conducted upon the non-shielded areas only.

For example, in one embodiment of the technical disclosure, the process to provide the desiccant layer 3 on the package cover plate 2 may be conducted as follows. The desiccant layer 3 is provided on the package cover plate 2 through evaporation coating with a metal mask plate; or the desiccant layer 3 is provided on the package cover plate 2 through electron beam evaporation with a metal mask plate; or the desiccant layer 3 is provided on the package cover plate 2 through magnetron sputtering with a metal mask plate; or the desiccant layer 3 is provided on the package cover plate 2 through physical vapor deposition with a metal mask plate.

Providing the desiccant layer 3 with a metal mask plate can make the formed desiccant layer 3 meet requirements on thickness and shape, thereby simplifying the process and improving the efficiency.

Certainly, those skilled in the art may use other feasible way to form the desiccant layer 3.

For example, as the desiccant layer 3 is provided on the package cover plate 2 through magnetron sputtering with a metal mask plate, magnetron reactive sputtering in the magnetron sputtering may be employed for forming the desiccant layer 3.

For example, FIG. 5 shows that a desiccant layer 3 is provided on a package cover plate 2 through magnetron reactive sputtering with a metal mask plate, i.e., a method for preparing a desiccant layer, which can be conducted as follows:

S501, an alkaline earth metal target, a metal mask and the package cover plate are placed in a sealed chamber;

S502, air in the sealed chamber is evacuated so as to form a vacuum chamber;

S503, a high frequency power is applied to the vacuum chamber; and

S504, oxygen gas is pumped into the vacuum chamber.

For example, the alkaline earth metal target may be a target having a single ingredient, such as a calcium target or barium target, or may also be a target of an alloy of metals, such as an alloy target of calcium and barium. Moreover, the metal target, may contain a small amount of rare earth metal, for example, 5 wt % of yttrium or lanthanum.

The alkaline earth metal target, the metal mask and the package cover plate are placed in the sealed chamber, for example, it is possible that the metal mask and the package cover plate are precisely aligned by a visual aligning (CCD) system, so as to ensure that the prepared desiccant layer is accurately positioned in the package area.

For example, after the alkaline earth metal target, the metal mask and the package cover plate are placed in the sealed chamber, air in the sealed chamber is evacuated to achieve a base vacuum of 1.0×10⁻⁵ Pa, so that a vacuum chamber is formed; oxygen gas is then pumped into the vacuum chamber so as to keep the vacuum degree between 0.01 Pa and 1 Pa; and next a radio frequency power is turn on for oxygen ionization, and ionized oxygen ions and metal ions react to produce a metal oxide, which is attached to the package cover plate to form the desiccant layer. Preferably, a high frequency power, such as a RF power at 13.56 MHZ, may be used as the radio frequency power.

When the desiccant layer is provided on the package cover plate through magnetron sputtering with a metal mask plate, providing of the desiccant layer 3 can be achieved simply, conveniently and fast, thereby simplifying the process and improving the efficiency of packaging the OLED display panel.

According to an embodiment of the technical disclosure, there is provided a display device, comprising the OLED display panel provided by any embodiment of the technical disclosure.

The embodiments of the technical disclosure being thus described, it will be obvious that the same may be varied in many ways. Such variations are not to be regarded as a departure from the spirit and scope of the technical disclosure, and all such modifications as would be obvious to those skilled in the art are intended to be included within the scope of the following claims.

1. An organic light emitting diode (OLED) display panel, comprising:
a substrate and a device disposed on the substrate;
a package cover plate, hermetically coupled to edges of the substrate so as to form a package cavity for packaging the device; and
a desiccant layer disposed on a side of the package cover plate facing the package cavity and for drying the device.

2. The OLED display panel according to claim 1, wherein one side of the package cover plate that forms the package cavity together with the substrate is a flat surface.

3. The OLED display panel according to claim 1, wherein the desiccant layer is an alkaline earth metal oxide layer or a metal getter layer.

4. The OLED display panel according to claim 3, wherein when the desiccant layer is the alkaline earth metal oxide layer, the thickness of the desiccant layer is in the range of 1-30 μm.

5. The OLED display panel according to claim 1, wherein the package cover plate is a glass package cover plate or a metal package cover plate.

6. The OLED display panel according to claim 1, wherein edges of the package cover plate and the substrate are hermetically coupled by sealant, and a thickness of the sealant is larger than a sum of a thickness of the desiccant layer and a thickness of the device.

7. The OLED display panel according to claim 1, wherein the desiccant layer is directly formed on the side of the package cover plate facing the package cavity.

8. A method for packaging an organic light emitting diode (OLED) display panel, comprising:
providing a desiccant layer on a package cover plate that is for drying a device on a substrate;
hermetically coupling edges of the package cover plate and the substrate, and sealing the desiccant layer and the device on the substrate within a package cavity formed by the package cover plate and the substrate.

9. The method according to claim 8, wherein providing the desiccant layer on the package cover plate comprising:
providing the desiccant layer on the package cover plate through evaporation coating with a metal mask plate; or
providing the desiccant layer on the package cover plate through electron beam welding with a metal mask plate; or
providing the desiccant layer on the package cover plate through magnetron sputtering with a metal mask plate; or
providing the desiccant layer on the package cover plate through physical vapor deposition with a metal mask plate.

10. The method according to claim 8, wherein providing the desiccant layer on the package cover plate through magnetron sputtering with a metal mask plate comprises:
placing an alkaline earth metal target, a metal mask and the package cover plate in a sealed chamber;
evacuating air in the sealed chamber so as to form a vacuum chamber;
pumping oxygen gas into the vacuum chamber; and
applying a high frequency power to the vacuum chamber.

11. The method according to claim 8, wherein hermetically coupling edges of the package cover plate and the substrate comprises:
coating sealant along edges of the package cover plate or the substrate, a thickness of the sealant being larger than a sum of a thickness of the desiccant layer and a thickness of the device;
pressing the package cover plate and the substrate; and
irradiating the sealant with ultraviolet (UV) so as to make it cured.

12. A display device, comprising the organic light emitting diode display panel according to claim 1.
